(19) United States
(12) Patent Application Publication
(10) Pub. No.: US 2005/0287740 A1
(43) Pub. Date: Dec. 29, 2005

(54) System and method of forming a split-gate flash memory cell

(75) Inventors: Michael Wu, Kaohsiung City (TW); Eugene Chu, Hsin-Chu (TW); Fei Yuh Chen, Hsinchu (TW); Yuh-Hwa Chang, Shulin City (TW); David Ho, Taichung City (TW); Kuang Yang, Baoshan Township (TW); Eric Chao, Hsinchu City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/875,429

(22) Filed: Jun. 24, 2004

(51) Int. Cl. H01L 21/336

(52) U.S. Cl. 438/257

(57) ABSTRACT

A system and method for forming a split-gate flash memory cell is disclosed. In one example, a method for forming a semiconductor device includes: supplying a substrate; forming a floating gate with alternate etch and passivation steps; and forming a control gate proximate to and partially overlying the floating gate.

### BACKGROUND

Memory devices include electrically erasable and programmable read-only memories (EEPROMs), and flash electrically erasable and electrically programmable read-only memories (flash EEPROMs). Generally, flash EEPROM cells, which comprise functions of electrical programming and erasing, may be classified into two categories: a stacked-gate structure and a split-gate structure.

One of the shortcomings of the stacked-gate structure is the “over-erasure” of the cell contents during erasure operations. During the process of memory content erasure and to ensure complete removal of the electrons previously injected, the erasure operation is normally sustained for a slightly prolonged time period. However, such a prolonged erasure operation may result in the removal of excess electrons. As a result, electron holes may form in the floating gate of the device. In severe cases, the stacked-gate transistor may become a depletion transistor, which conducts even in the absence of a control voltage at the control gate. This phenomenon is known as memory over-erasure.

To overcome the shortcomings of memory over-erasure by stacked-gate EEPROM devices, split-gate EEPROM devices were conceived. Typically, such a memory device comprises a transistor that includes a control gate and a floating gate. The principal advantage of such a configuration is that the memory transistor is not affected by the state of the floating gate. Instead, it maintains its off state, even if the floating-gate is subject to the phenomenon of over-erasure and therefore, is in a conductive state. Accordingly, the memory cell can maintain its correct state irrespective of the over-erasure condition.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a cross-sectional view of one embodiment of a partial semiconductor device during fabrication.

FIG. 2 is a cross-sectional view of one embodiment of a partial semiconductor device comprising a floating gate during fabrication.

FIG. 3 is a cross-sectional view of one embodiment of a partial semiconductor device comprising floating and control gates.

### DETAILED DESCRIPTION

The present disclosure relates generally to the manufacturing of semiconductor devices, and more particularly to a system and method of forming split-gate flash memory cells.

For the purposes of promoting an understanding of the principles of the invention, references will now be made to the embodiments or examples illustrated in the drawings, and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates.

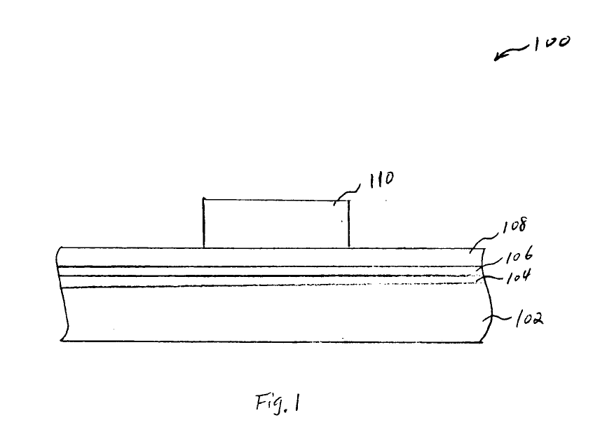

Referring now to FIG. 1, shown therein is a cross-sectional view of one embodiment of a partial semiconductor device 100 during fabrication. In this embodiment, the semiconductor device 100 may comprise a substrate 102. The substrate 102 may comprise silicon, silicon-on-insulator (SOI), silicon with defective crystalline, and/or diamond or other suitable materials. The substrate 102 may be n-type doped or p-type doped, and is n-type doped in the present example for purposes of illustration. The substrate 102 may be provided with one or more isolation features (not shown). The isolation features may comprise local oxidation of silicon (LOCOS) structures and/or shallow trench isolation (STI) structures that are formed in the substrate 102 to electrically isolate device areas.

In furtherance of the example, an insulating layer 104 may be deposited or formed over the substrate 102. The insulating layer 104 may comprise a variety of different materials, including but not limited to, SiO₂, SiC, CN, and SiOC. The insulating layer 104 may be used as a metal-oxide semiconductor (MOS) gate oxide, a thermal oxide, carbon nitride, or any other appropriate gate dielectric film. It is contemplated that the insulating layer 104 may be too thin to be of any appreciable significance. Alternatively, it may have a thickness that is suitable for a gate oxide. Formation of the insulating layer 104 may include an Argon (Ar) plasma clean process prior to the growth of the insulating layer 104. Native oxide may be cleaned from the substrate 102 by the plasma clean process, and the insulating layer 104 may be deposited “in situ” of the plasma clean process. The insulating layer 104 may be formed by a plurality of different methods. For example, the insulating layer 104 may be formed upon exposure to air wherein about 3 Angstroms to about 15 Angstroms of native oxide may form on the semiconductor substrate 102. Alternatively, the substrate 102 may be processed, so that the insulating layer 104 of SiO₂ may be formed by a low temperature Rapid Thermal Processing (RTP) or thermal process. The transfer to the process for forming the insulating layer 104 may be accomplished under an inert gas or vacuum environment.

In furtherance of the example, a gate dielectric 106 is formed on or over the insulating layer 104 and/or the substrate 102. The gate dielectric 106 may comprise any suitable material. In one example, the gate dielectric 106 may comprise traditional dielectric materials, such as doped or undoped polysilicon, nitrogen, silicon, silicon nitride, silicon oxynitride, silicon carbide, metal silicide, metal oxide, a barrier layer and metal conductor, a barrier layer and a non-metal conductor or other suitable materials and structures. In another example, the gate dielectric 106 may comprise high-k dielectric material, such as TaN, TiN, Ta₂O5, HfO₂, ZrO₂, HfSiON, HfSix, HfSixNy, HfAlO₂, NiSix, silicon nitride, aluminum oxide, tantalum pentoxide, zirconium oxide, barium strontium titanate, lead-lanthanum-zirconim-titanate, or other suitable materials. The gate dielectric 106 may be formed by atomic layer deposition (ALD), chemical vapor deposition (CVD), plasma enhanced chemical vapor deposition (PECVD), evaporation, and/or other methods. Generally, the gate dielectric 106 may have a thickness of less than approximately 50 Angstroms. However, other thicknesses are also contemplated for the gate dielectric 106. In one example, materials, such as HfO₂, may be blanket-deposited on or over the insulating layer 104 to form the gate dielectric 106. In another example, gate dielectric materials may be selectively deposited. In a third example, it may be desirable to blanket deposit some materials, such as HfO₂, in some fabrication processes, while selectively depositing the same materials in other processes.

In furtherance of the example, the gate dielectric 106 is formed by ALD, which may provide good step coverage (even on large areas) and a dense and pinhole free structure. ALD may be particularly useful for the deposition of metals and metal oxides in high packing density and/or high aspect ratio applications that include relatively demanding thin film requirements. In ALD, films grow with a relatively constant growth rate, and each deposition cycle ideally produces one molecular layer of the deposited material on the substrate surface. However, in reality, the growth rate is below one molecular layer per cycle, as the absorbed source chemical molecules may be bulky or the substrate temperature may affect the number of active sites (e.g., —OH groups) on the substrate surface. Metal oxide thin films produced by ALD are generally uniform and have desirable adhesion properties that allow them to become firmly bonded to the substrate surface.

In this example, the ALD of a high-k material, such as HfO₂, may be achieved by co-reacting a precursor in the presence of a gas, and then purging the precursor using the same gas. For HfO₂, ALD may utilize a precursor of Hf, such as HfCl₄, or other organometallic Hf sources having a variety of ligands attached to the Hf atom. For example, appropriate precursors may include HfCl₄ or Hf(OR)₄, wherein R is an alkyl such as CH(CH₃)₂; Hf(tmdh)₄, wherein tmdh=2,2,6,6-tetramethyl-3,5-heptanedionato; Hf(tfac)₄, wherein tfac=trifluoroacetylacetonate; or Hf(NO₃)₄. Similar precursors may be used for the ALD of other high-k materials, such as ZrO₂. Because carbon containing hafnium precursors may result in excessive carbon and fluorine incorporation in the metal oxide film, HfCl₄ may be a desirable choice, as it may result in limited residual chlorine incorporation. HfCl₄ may also be a desirable metal oxide precursor, because it may be sublimated by injection and vaporization into the process reactor.

In furtherance of the example, H₂O vapor may be selected as an oxygen source for the HfO₂. Here, a HfO₂ deposition process may be accomplished at a temperature ranging between about 200° C. and about 400° C., and with a deposited film thickness ranging between about 3 Angstroms and about 75 Angstroms. The ALD process may be performed in cycles with a series of HfO₂ monolayers formed during each cycle, until the desired film thickness is achieved for the gate dielectric 106. However, other temperatures and thicknesses are also contemplated by the present disclosure.

In furtherance of the example, a gate layer 108 may be deposited on or over the dielectric layer 106. The gate layer 108 may comprise polycrystalline silicon, Cu, Al, Ni, Co, metal silicide, fungsten, silicide or other suitable materials. The gate layer 108 may be formed by a variety of methods, such as CVD, PVD, ALD, or other suitable methods. In one example, the gate layer 108 may be formed at a temperature ranging from about 470° C. to about 770° C., and to a thickness ranging from about 1200 Angstroms to about 1800 Angstroms. However, other temperatures and thicknesses are also contemplated for forming the gate layer 108.

In furtherance of the example, a photoresist layer 110 may be formed over the gate layer 108 by methods now known or later developed.

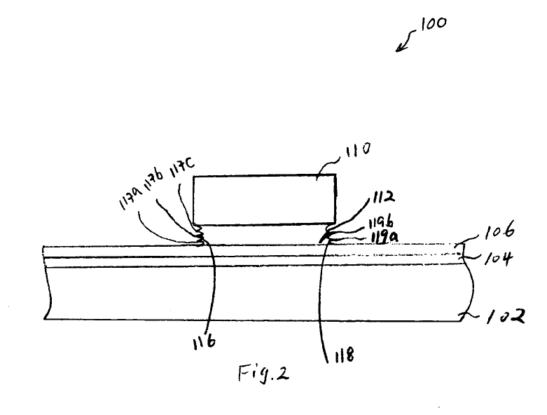

Referring now to FIG. 2, shown therein is a cross-sectional view of one embodiment of the partial semiconductor device 100 with a floating gate 112 during fabrication. In this embodiment, the floating gate 112 may be formed by etching the gate layer 108 in FIG. 1. The etching process may comprise a plasma process or other suitable processes, and may utilize alternate etch and passivation steps that were originally conceived by Robert Bosch GmbH of Germany, for example. In one example, Advanced Si Etch, developed by Surface Technology Systems Ltd of the United Kingdom may be utilized to form the floating gate 112. The partial semiconductor device 100 of FIG. 1 may be processed in a plasma chamber, such as a Surface Technology Systems multiplex inductively coupled plasma system, for the etching process.

In particular, the formation of the floating gate 112 may commence with an initial gas stabilization period of approximately 30 seconds, during which SF₆, which may be of electronic grade and with high purity, may be dispersed into the plasma chamber with a mass flow controller. Following the gas stabilization period, alternate etch and passivation steps may be employed to process the partial semiconductor device 100. During a passivation step, polymer, which may comprise CFₙ (n being a positive integer) from the C₄F₈ passivant gas, may be deposited over the surface of the gate layer 108. During the etch step, the deposited polymer may be removed from the horizontal surface of the gate layer 108 by reactive ion etching. Since ion energy is higher in the vertical direction, polymer may be removed from the horizontal surface at a much higher rate than from the vertical side walls of the gate layer 108. Following the polymer removal, the exposed surface of the gate layer 108 may be further etched by being exposed to reactive fluorine-based species, for example. By repeating the passivation and etch steps, the floating gate 112 of FIG. 2, which comprises multiple tips on both side walls 116 and 118, is formed.

It is contemplated that on the side wall 116, multiple tips 117a, 117b, and 117c may be evenly distributed or unevenly distributed. Likewise, on the side wall 118, multiple tips 119a and 119b may be evenly distributed or unevenly distributed. It is further contemplated that a fewer or a greater number of multiple tips may reside on each of the side walls 116 and 118. Further, the multiple tips 117a, 117b, 117c, 119a and 119b may comprise identical shapes and/or sizes, or that at least two of them may comprise different shapes and/or sizes.

It is contemplated that besides SF₆, any other suitable gas may be used as the etchant gas. Further, it is contemplated that besides C₄ F₈, any other suitable gas may be used as the passivant gas. Advanced Si Etch is further described in Ashraf et al., “Defining Conditions for the Etching of Silicon in an Inductive Coupled Plasma Reactor,” Proceedings of the Materials Research Society Fall Meeting, Boston, Mass., Nov. 29-Dec. 3, 1999.

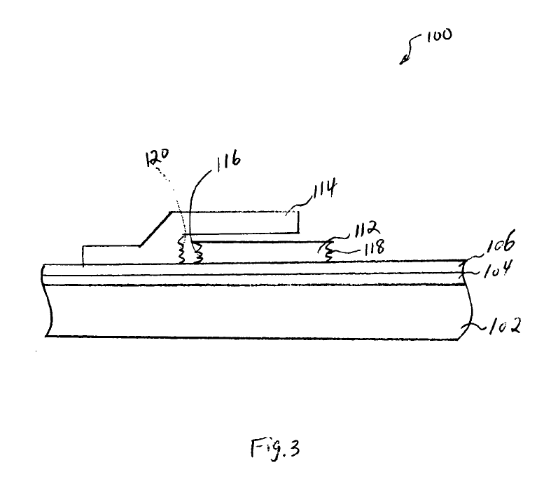

Referring now to FIG. 3, shown therein is a cross-sectional view of one embodiment of the partial semiconductor 100 device with a floating gate 112 and a control gate 114. As shown, the photoresist mask 110 shown in FIG. 2 has been removed by methods now known or to be developed. The control gate 114 and insulation (not shown) between the floating gate 112 and the control gate 114 are formed according to methods now known or to be developed. Since the side wall 116 of the floating gate 112 may comprise multiple tips, a side wall 120 of the control gate 114 may also comprise multiple tips to compliment the shape of the side wall 116. It is noted that the formation of those multiple tips of the control gate 114 does not require any special procedures or methods, as they are naturally developed during the formation of the control gate 114 by any known or to be developed methods.

The above embodiments provide a simplified process of forming split-gate flash memory cells, thereby reducing the cost of producing split-gate flash memory cells. In addition, multiple tips formed on the side walls of the control and floating gates also help to improve the erasure efficiency of the split-gate flash memory cells.

Although only a few exemplary embodiments of this invention have been described in detail above, those skilled in the art will readily appreciate that many modifications are possible in the exemplary embodiments without materially departing from the novel teachings and advantages of this invention. In one example, only one of the side walls 116 and 118 may comprise multiple tips. In another example, the side wall 120 may not comprise multiple tips. Also, features illustrated and discussed above with respect to some embodiments can be combined with features illustrated and discussed above with respect to other embodiments. Accordingly, all such modifications are intended to be included within the scope of this invention.

1. A method for forming a semiconductor device, comprising:
supplying a substrate;
forming a floating gate on the substrate with alternate etch and passivation steps; and
forming a control gate proximate to and partially overlying the floating gate.

2. The method of claim 1 wherein forming a floating gate comprises forming the floating gate in a plasma chamber.

3. The method of claim 1 wherein forming a floating gate comprises depositing a polymer and removing the polymer.

4. The method of claim 1 wherein forming a floating gate comprises depositing a polymer and removing the polymer by reactive ion etching.

5. The method of claim 1 wherein forming a floating gate comprises exposing a floating gate layer surface to reactive fluorine-based species.

6. The method of claim 1 wherein forming a floating gate comprises exposing a floating gate layer surface to a passivant gas of C₄F₈.

7. The method of claim 1 wherein forming a floating gate comprises exposing a floating gate layer surface to an etchant gas of SF₆.

8. The method of claim 1 wherein the floating gate comprises side walls with a plurality of tips.

9. The method of claim 1 wherein the control gate comprises a side wall with a plurality of tips.

10. A flash memory cell, comprising:
a floating gate with at least one side wall having a plurality of tips; and
a control gate wherein the control gate is at least partially overlying the floating gate.

11. The flash memory cell of claim 10 wherein the control gate comprises a plurality of tips on a side wall.

12. The flash memory cell of claim 10 wherein the plurality of tips are formed in a plasma chamber.

13. The flash memory cell of claim 10 wherein the plurality of tips are formed by alternate etch and passivation steps.

14. The flash memory cell of claim 13 wherein the etch step comprises removing a polymer from a floating gate layer.

15. The flash memory cell of claim 13 wherein the etch step comprises removing a polymer from a floating gate layer by reactive ion etching.

16. The flash memory cell of claim 13 wherein the etch step comprises exposing a floating gate layer surface to reactive fluorine-based species.

17. A method for forming a flash memory cell, comprising:
supplying a substrate;
forming a floating gate with alternate etch and passivation steps to create multiple tips on side walls of the floating gate; and
forming a control gate with multiple tips on a side wall proximate and facing multiple tips on one of the side walls of the floating gate.

18. The method of claim 17 wherein forming a floating gate comprises forming the floating gate in a plasma chamber.

19. The method of claim 17 wherein the etch step comprises removing a polymer.

20. The method of claim 17 wherein the etch step comprises removing a polymer by reactive ion etching, and exposing a floating gate layer surface to reactive fluorine-based species.

21. The method of claim 17 wherein the passivation step comprises depositing a polymer over a floating gate layer.
